(19) United States
(12) Patent Application Publication
(10) Pub. No.: US 2026/0282962 A1
(43) Pub. Date: Sep. 17, 2026

(54) POWER MANAGEMENT CIRCUIT HAVING THIN-FILM INDUCTORS

(71) Applicant: QUALCOMM Incorporated, San Diego, CA (US)

(72) Inventors: Kai LIU, San Diego, CA (US); Jui-Yi CHIU, Taichung City (TW); Jonghae KIM, San Diego, CA (US)

(21) Appl. No.: 19/080,569

(22) Filed: Mar. 14, 2025

(51) Int. Cl. H01L 23/538; H01L 25/18; H10D 1/20

(52) U.S. Cl. CPC H10W 70/65; H10D 1/20; H10W 70/611; H10W 90/00

(57) ABSTRACT

In an aspect, an electronic device includes a die substrate; a substrate overlying the die substrate, the substrate having one or more non-magnetic dielectric layers, and a central region and a side region adjacent the central region; a set of metallizations extending through the one or more non-magnetic dielectric layers of the central region of the substrate, wherein the set of metallizations are connected to control lines of the die substrate; and a solenoid thin-film inductor (TFI) disposed in the one or more non-magnetic dielectric layers of the side region, the solenoid TFI comprising a central magnetic block, one or more magnetic blocks disposed adjacent to opposite ends of the central magnetic block, and conductive windings disposed about the central magnetic block.

### FIELD OF DISCLOSURE

The present disclosure generally relates to electronic packaging and, more particularly, to a power management integrated circuit (PMIC) having thin-film inductors.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system-on-a-chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

In advanced electronic packaging, package miniaturization has become desirable due to the growing need for compact, high-performance devices in consumer electronics, automotive systems, and medical technologies. As electronic systems move toward the desired miniaturization goals, the space in an electronic package available to power management components is greatly reduced. Although the space available for power management components is reduced, the power performance requirements of such power management components have increased in such aspects as power density, voltage stability, current stability, power system noise, heat dissipation, etc.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device includes a power management integrated circuit (PMIC) substrate; a substrate overlying the die substrate, the substrate having one or more non-magnetic dielectric layers, and a central region and a side region adjacent the central region; a set of metallizations extending through the one or more non-magnetic dielectric layers of the central region of the substrate, wherein the set of metallizations are connected to control lines of the die substrate; and a solenoid thin-film inductor (TFI) disposed in the one or more non-magnetic dielectric layers of the side region, the solenoid TFI comprising a central magnetic block, one or more magnetic blocks disposed adjacent to opposite ends of the central magnetic block, and conductive windings disposed about the central magnetic block.

In an aspect, a power management circuit includes a power management integrated circuit (PMIC) substrate; a substrate overlying the die substrate, the substrate having one or more non-magnetic dielectric layers, a central region, and a side region adjacent the central region; a set of metallizations extending through the one or more non-magnetic dielectric layers of the central region of the substrate, wherein the set of metallizations are connected to control lines of the die substrate; and a solenoid thin-film inductor (TFI) disposed in the one or more non-magnetic dielectric layers of the side region, the solenoid TFI comprising a central magnetic block, one or more magnetic blocks disposed adjacent to opposite ends of the central magnetic block, and conductive windings disposed about the central magnetic block.

In an aspect, a method of fabricating a power management circuit includes receiving a die substrate for processing; and forming a substrate over the die substrate, the substrate having one or more non-magnetic dielectric layers, a central region and a side region adjacent the central region, a set of metallizations extending through the one or more non-magnetic dielectric layers of the central region of the substrate, wherein the set of metallizations are connected to control lines of the die substrate, a solenoid thin-film inductor (TFI) disposed in the one or more non-magnetic dielectric layers of the side region, the solenoid TFI comprising a central magnetic block, one or more magnetic blocks disposed adjacent to opposite ends of the central magnetic block, and conductive windings disposed about the central magnetic block.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 depicts an example power management circuit, according to aspects of the disclosure.

FIG. 2 depicts an example power management circuit, according to aspects of the disclosure.

FIG. 3 shows an example solenoid thin film inductor, according to aspects of the disclosure.

FIG. 4A through FIG. 4F show example steps that may be undertaken to fabricate a power management circuit, according to aspects of the disclosure.

FIG. 5 shows an example method of fabricating a power management circuit, according to aspects of the disclosure.

FIG. 6 illustrates a profile view of a package that includes a surface mount substrate, an integrated device, and an integrated passive device, according to aspects of the disclosure.

FIG. 7 illustrates an example method for providing or fabricating a package that includes an integrated device comprising a power management control circuit, according to aspects of the disclosure.

FIG. 8 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

As used herein, the term “metallization” refers to the patterned metallization layers, the metalized vias, and the contacts formed in and on a substrate that are configured to electrically connect the electrical components mounted on or in the substrate.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

The miniaturization of power management circuits has facilitated advancements in modern electronics, enabling higher efficiency, reduced form factors, and enhanced thermal performance in compact devices. Power management circuits may integrate multiple voltage regulators, DC-DC converters, and protection circuits into a single package, reducing PCB footprint and improving power efficiency. Low-profile inductors may be employed to optimize power density and thermal performance in switching regulators. These inductors offer high inductance values with minimal height, making them ideal for ultra-thin consumer electronics, such as smartphones, tablets, and wearables. Additionally, their low DC resistance and improved saturation characteristics help reduce power losses, enhance transient response, and support high switching frequencies, enabling smaller passive components.

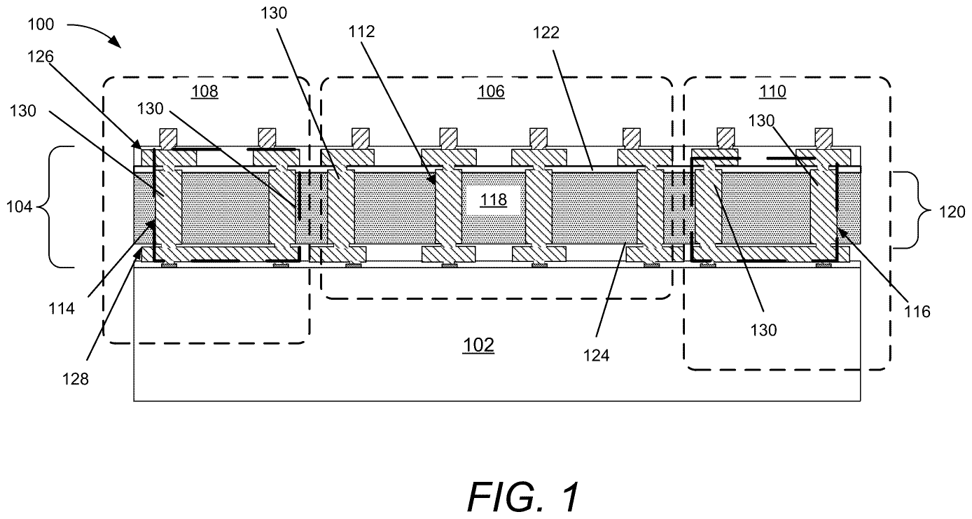

FIG. 1 depicts an example power management circuit 100, according to aspects of the disclosure. In this example, the power management circuit 100 includes a power management integrated circuit (PMIC) substrate 102 and a passive component substrate 104 overlying the PMIC substrate 102. The PMIC substrate 102 includes the active circuitry associated with the operation of the power management circuit 100, while the passive component substrate 104 includes one or more passive components that are connected to the active circuitry of the PMIC substrate 102.

In FIG. 1, the passive component substrate 104 includes a central region 106, a first side region 108 adjacent to the central region 106, and a second side region 110 adjacent to the central region 106 opposite the first side region 108. The central region 106 includes a set of metallizations 112 that are connected to the control lines of the active circuitry formed in the PMIC substrate 102. Side region 108 includes a thin-film inductor (TFI) 114, while side region 110 includes a TFI 116. According to aspects of the disclosure, the magnetic dielectric layer 118 spans a dielectric region 120 defined by an upper interior surface 122 of the passive component substrate 104 and a lower interior surface 124 of the passive component substrate 104. As used herein, a magnetic material may be a material having a relative permeability μᵣ between about 10 to 10,000, with a typical relative permeability range between about 10 and 1500. It will be recognized that the relative permeability of a magnetic material may be dependent on the material composition and frequency of operation.

In an aspect, a TFI is a small electronic component that stores and controls magnetic energy using a magnetic field. Here, both TFI 114 and 116 include coils formed by a set of metallizations, including patterned metallization layer 126, patterned metallization layer 128, and pillars 130. As shown, the coils are disposed about the magnetic dielectric layer 118. Each TFI 114 and 116 is connected to the power lines of the PMIC substrate 102.

Certain aspects of the disclosure are implemented with the recognition that large electrical currents flow through each of the TFIs 114 and 116 during normal operation of the power management circuit 100. The large electrical currents flowing through the TFIs 114 and 116, in turn, generate large magnetic fields that may extend into the central region 106 and disrupt control signals in the set of metallizations 112 (e.g., by inducing noise and/or other parasitic inductive interferences in the set of metallizations 112). As such, the TFIs 114 and 116 may need to be spaced away from the set of metallizations 112 by a sufficient distance to reduce the magnitude of the magnetic field permeating the set of metallizations 112. However, such spacing undesirably increases the area occupied by the power management circuit 100. If a closer spacing is necessary based on miniaturization requirements, the reduced spacing between the TFIs 114 and 116 and the set of metallizations 112 may impose limitations on the current and frequency of the signals flowing through the TFIs 114 and 116, which may reduce the overall performance of the power management circuit 100.

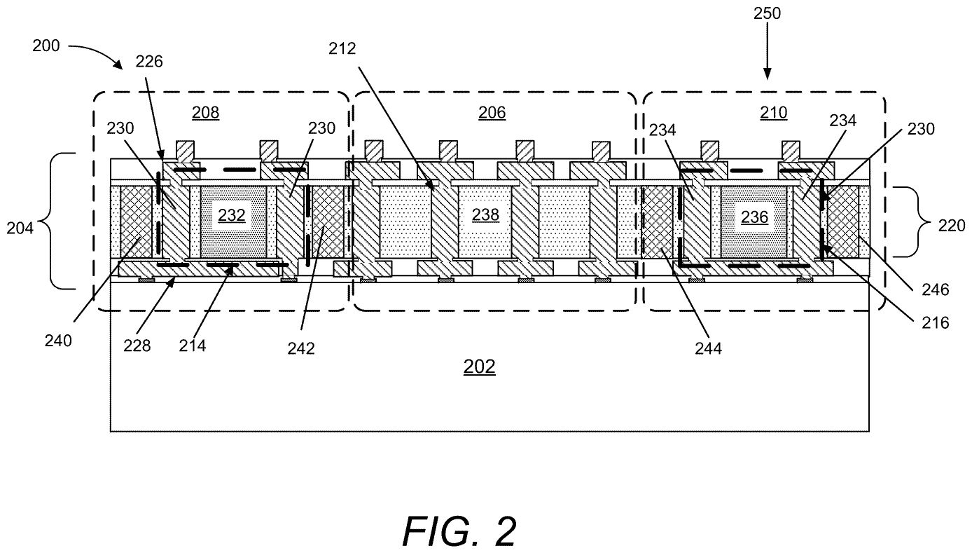

FIG. 2 depicts an example power management circuit 200, according to aspects of the disclosure. In this example, the power management circuit 200 includes a die substrate 202 (e.g., a PMIC substrate) and a passive component substrate 204 overlying the die substrate 202. The die substrate 202 includes the active circuitry associated with the operation of the power management circuit 200, while the passive component substrate 204 includes one or more passive components that are connected to the active circuitry of the die substrate 202.

In FIG. 2, the passive component substrate 204 includes a central region 206, a first side region 208 adjacent to the central region 206, and a second side region 210 adjacent to the central region 206 opposite the first side region 208. The central region 206 includes a set of metallizations 212 that are connected to the control lines of the active circuitry formed in the die substrate 202. Side region 208 includes a solenoid TFI 214, while side region 210 includes a solenoid TFI 216. According to aspects of the disclosure, solenoid TFI 214 includes coils formed by a set of metallizations, including patterned metallization layer 226, patterned metallization layer 228, and pillars 230 that are disposed about a magnetic block 232. Similarly, solenoid TFI 216 includes coils formed by a set of metallizations, including patterned metallization layer 226, patterned metallization layer 228, and pillars 234 that are disposed about a magnetic block 236. Each solenoid TFI 214, 260 is connected to the power lines of the die substrate 202.

Unlike the power management circuit 100 shown in FIG. 1, the power management circuit 200 includes a non-magnetic dielectric layer 238. In an aspect, the non-magnetic dielectric layer 238 spans the entire height of the dielectric region 220. Here, the magnetic blocks 232, 236 are disposed in the non-magnetic dielectric layer 238.

According to aspects of the disclosure, the inductive coupling between the set of metallizations 212 and the solenoid TFIs 214, 216 is reduced by passing the pillars 230, 234 through the non-magnetic dielectric layer 238. Additionally, the inductive coupling is further reduced by the design of the magnetic blocks 232, 236. As discussed in further detail herein, the magnetic blocks 232, 236 are shaped so as to concentrate the magnetic fields of each solenoid TFI 214, 216 in a manner that minimizes the parasitic inductance caused by the solenoid TFIs 214, 216 in the set of metallizations 212.

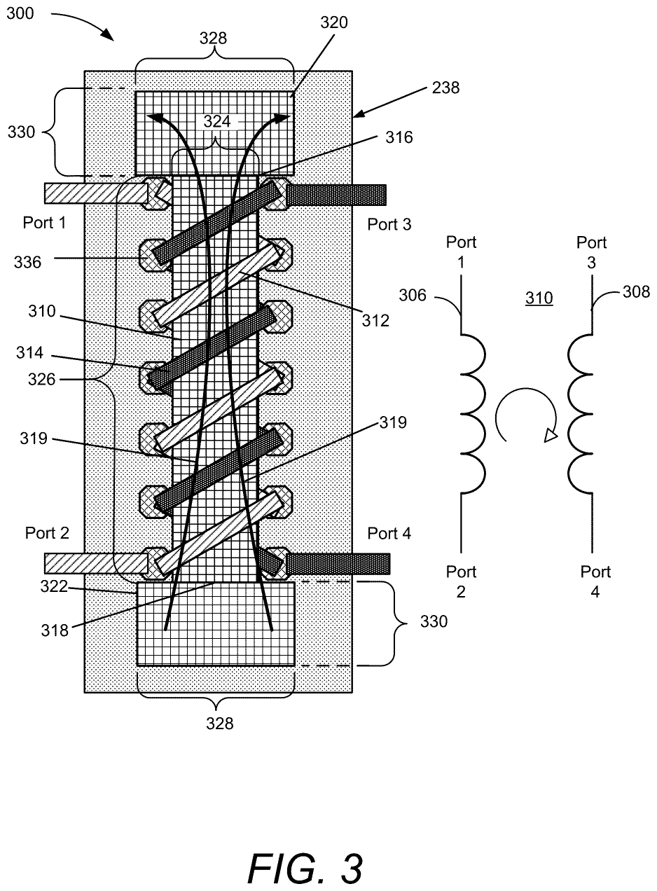

FIG. 3 shows an example solenoid TFI 300, according to aspects of the disclosure. In this example, the solenoid TFI 300 is shown from the perspective of arrow 250 of FIG. 2. As shown, the solenoid TFI is at least partially embedded in the non-magnetic dielectric layer 238 of FIG. 2. Unlike typical solenoid TFIs, the solenoid TFI 300 is implemented with features that assist in concentrating the magnetic field at the end portions of the solenoid TFI 300 thereby allowing the solenoid TFI 300 to be placed in closer proximity to the metallizations connected to the control lines of a corresponding die substrate. That is, the example solenoid TFI 300 may be placed closer to the metallizations connected to the control lines when compared to conventionally constructed solenoid TFIs, which typically require a larger spacing between the inductor and the metallizations connected to the control lines.

As shown in FIG. 3, the solenoid TFI 300 is a four-port inductor comprising two inductive elements 306, 308 (shown schematically at 310). Here, the solenoid TFI 300 includes a central magnetic block 310 and a first conductive winding 312 formed about the central magnetic block 310 corresponding to inductive element 306. The solenoid TFI 300 also includes a second conductive winding 314 that is formed about the central magnetic block 310 corresponding to inductive element 308. The first conductive winding 312 and second conductive winding 314 extend about the central magnetic block 310, and each terminate at opposite ends 316 of the central magnetic block 310. As will be understood, the conductive windings lying over the central magnetic block 310 are formed by the patterns of patterned metallization layer 226 shown in FIG. 2. Similarly, the conductive windings lying under the central magnetic lack are formed by the patterns of patterned metallization layer 228 shown in FIG. 2. The conductive windings lying above and below the central magnetic block 310 are connected by pillars 336 (e.g., pillars 230 of FIG. 2).

As noted, the solenoid TFI 300 includes features that alter the magnetic field (represented here by magnetic field lines 319) in a manner that allows the solenoid TFI 300 to be placed in closer proximity to the metallizations connected to the control lines of the PMIC substrate. To this end, the solenoid TFI 300 includes a first magnetic block 320 adjacent to the end 316 of the central magnetic block 310. Additionally, the solenoid TFI 302 includes a second magnetic block 322 adjacent to the end 318 of the central magnetic block 310.

In an aspect, the magnetic blocks 310, 320, and 322 may be formed from a single sheet of non-conducting magnetic material. Alternatively, the magnetic blocks 310, 320, and 322 may be individual structures formed from the same or different magnetic materials.

In the example shown in FIG. 3, the central magnetic block 310 of the solenoid TFI 302 has a width 324 and a length 326. Similarly, the first magnetic block 320 and the second magnetic block 322 each have a width 328 and length 330. Here, the width 328 of the magnetic blocks 320 and 322 is greater than the width 324 of the central magnetic block 310. In an aspect, the width 328 may be between 25% and 35% of the width 324. Further, the length 330 may be greater than about 20% of the length 326. However, it will be recognized, based on the teachings of the present disclosure, that the specific relative dimensions may vary based on the solenoid TFI design specifications.

As shown in FIG. 3, the first magnetic block 320 and the second magnetic block 322 at opposite ends of the central magnetic block 310 increase the magnetic flux at the ends of the solenoid TFI 300 and thereby boost the self-inductance of the solenoid TFI to some extent.

With reference again to FIG. 2, certain aspects of the disclosure are implemented with a recognition that the solenoid TFIs 214, 216 often carry large currents. Such large currents may create “hot spots” at the portions of the passive component substrate 204 proximate to the solenoid TFIs 214, 216. Such hot spots correspond to areas within the passive component substrate 204 having an elevated temperature that may impede the performance of the power management circuit 200.

Certain aspects of the disclosure are directed to the inclusion and placement of thermal blocks near potential hot spots. In FIG. 2, a first set of thermal blocks 240, 242 are disposed in the non-magnetic dielectric layer 238 at the first side region 208 of the passive component substrate 204. In an aspect, the first set of thermal blocks 240, 242 are placed in close proximity (e.g., between about 20 micrometers and 30 micrometers) to pillars 230 of the solenoid TFI 214. In FIG. 2, the thermal blocks 240, 242 may span the entire height of the dielectric region 220 and may be formed from any material (e.g., copper or other thermal interface (TIM) material) having a high degree of thermal conductivity so as to be able to dissipate heat generated at the solenoid TFI 214.

As also shown in FIG. 2, a second set of thermal blocks 244, 246 are disposed in the n-magnetic dielectric layer 238 at the second side region 210 of the passive component substrate 204. In an aspect, the second set of thermal blocks 244, 246 are placed in close proximity to pillars 234. In FIG. 2, the thermal blocks 244, 246 may span the entire height of the dielectric region 220 and may be formed from any material (e.g., copper or TIM-thermal interface material) having a high degree of thermal conductivity so as to be able to dissipate heat generated at solenoid TFI 216.

In an aspect, the thermal blocks are arranged to disburse heat generated at the side regions 208, 210 before the heat may be transferred to the central region 206. In FIG. 2, the thermal block 242 is disposed between the solenoid TFI 214 and the first set of metallizations 212. Similarly, thermal block 244 is disposed between the solenoid TFI 216 and the first set of metallizations 212.

In an aspect, certain thermal blocks may be arranged to disburse heat generated at the side regions 208 and 210 to the ambient environment exterior to the ends of the side regions 208 and 210. In FIG. 2, thermal block 240 is disposed between the solenoid TFI 214 and the outer edges of the side region 208. Similarly, thermal block 246 is disposed between the solenoid TFI 216 and the outer edges of the side region 210.

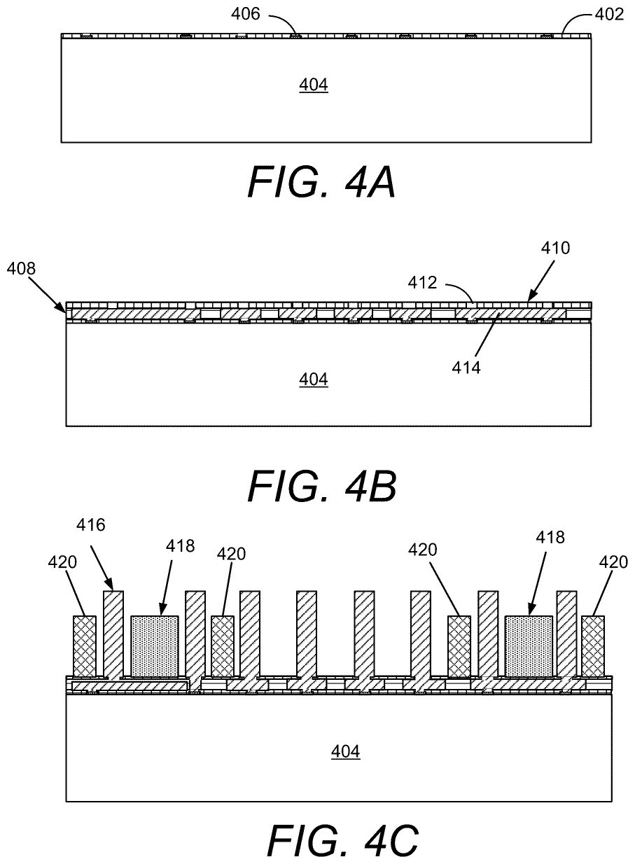

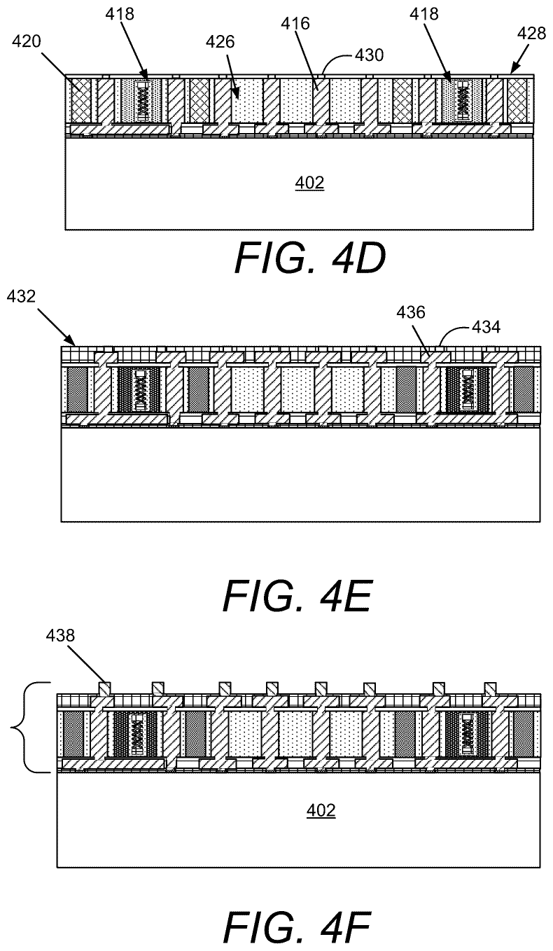

FIG. 4A through FIG. 4F show example steps that may be undertaken to fabricate a power management circuit, according to aspects of the disclosure. At FIG. 4A, a passivation layer 402 is formed over an upper surface of a die substrate 404. The passivation layer 402 is patterned, and metal is deposited in the openings of the pattern to form contacts 406. The contacts 406 provide the connections between the control lines and power lines of the die substrate 404 and the passive component substrate ultimately formed over the die substrate 404.

At FIG. 4B, a first redistribution layer 408 is formed over the passivation layer 402. The first redistribution layer 408 includes patterned metal lines 414 used for the conductive windings of the solenoid TFI. A further passivation layer 410 is formed over the first redistribution layer 408 and patterned with openings 412 overlying the metal lines 414. In an aspect, the first redistribution layer 408 may have a thickness of approximately 15 micrometers.

At FIG. 4C, the pillars 416 of the solenoid TFIs are formed. In an aspect, the pillars 416 may be electroplated into the openings 412 of the passivation layer 410. In an aspect, the pillars 416 may be electroplated to a height of about 130 micrometers. Additionally, the magnetic blocks 418 and thermal blocks 420 are placed between the pillars 416 using, for example, a pick-and-place operation.

At FIG. 4D, a non-conducting, non-magnetic material 426 (e.g., an epoxy) is deposited over the pillars 416, thermal blocks 420, and magnetic blocks 418. The non-conducting, non-magnetic material 426 and the pillars 416 are grinded back to, for example, a height of 100 micrometers to expose the pillars 416 for subsequent wafer processes. In an aspect, the thermal blocks 420 and magnetic blocks 418 need not be grinded back if they have been prefabricated to the desired height. Additionally, a further passivation layer 428 is deposited over the grinded back structure and patterned with openings 430.

At FIG. 4E, another redistribution layer 432 is formed over the further passivation layer 428. In an aspect, the redistribution layer 432 may include patterned lines 436 that form the conductive windings of the solenoid TFIs. Here, the redistribution layer 432 may have a thickness of about 15 micrometers. Openings 434 overlying selected lines (e.g., patterned lines 436) are formed in the redistribution layer 432. At FIG. 4F, an under-bump metallization operation is performed, followed by the plating of bumps 438 to finish the fabrication of the passive component substrate 440 that overlies the die substrate 404.

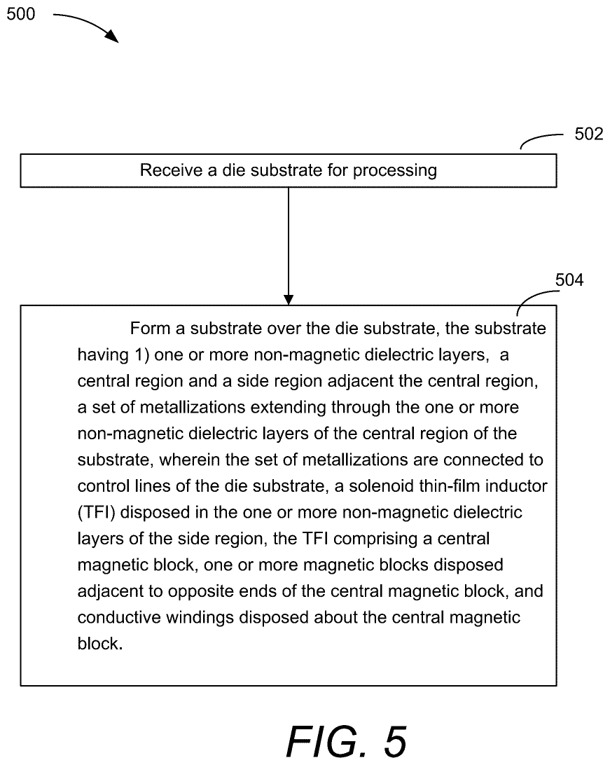

FIG. 5 shows an example method 500 of fabricating a power management circuit, according to aspects of the disclosure. At operation 502, a die substrate is received for processing. At operation 504, a substrate is formed over the die substrate. The substrate has 1) one or more non-magnetic dielectric layers, 2) a central region and a side region adjacent the central region, 3) a set of metallizations extending through the one or more non-magnetic dielectric layers of the central region of the substrate, wherein the set of metallizations are connected to control lines of the die substrate, 4) a solenoid thin-film inductor (TFI) disposed in the one or more non-magnetic dielectric layers of the side region, the TFI comprising a central magnetic block, one or more magnetic blocks disposed adjacent to opposite ends of the central magnetic block, and conductive windings disposed about the central magnetic block.

A technical advantage of the method 500 is that it provides a power management circuit architecture having on-chip inductors that may be operated at high switching frequency and high power without substantially interfering with control signals needed for a power management integrated circuit substrate.

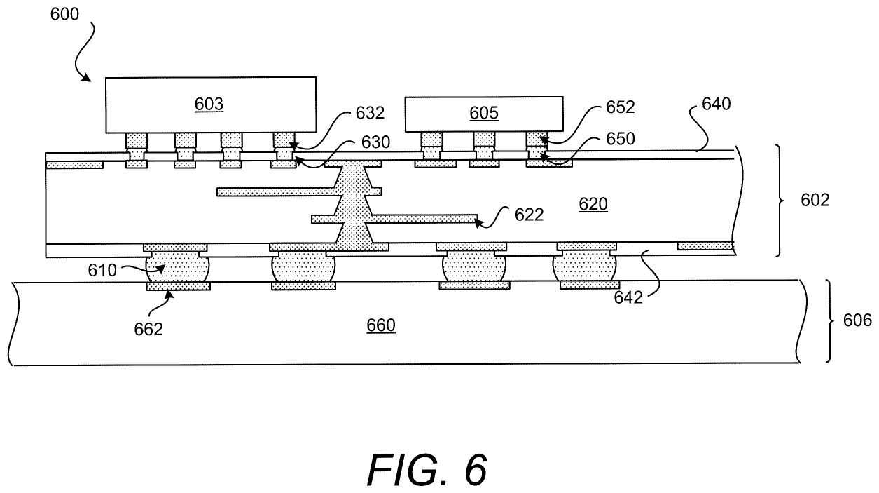

FIG. 6 illustrates a profile view of a package 600 that includes a surface mount substrate 602, an integrated device 603, and an integrated passive device 605, according to aspects of the disclosure. The package 600 may be coupled to a printed circuit board (PCB) 606 through a plurality of solder interconnects 610. The PCB 606 may include at least one board dielectric layer 660 and a plurality of board interconnects 662.

The surface mount substrate 602 includes at least one dielectric layer 620 (e.g., substrate dielectric layer), a plurality of interconnects 622 (e.g., substrate interconnects), a solder resist layer 640 and a solder resist layer 642. The integrated device 603 may be coupled to the surface mount substrate 602 through a plurality of solder interconnects 630. The integrated device 603 may be coupled to the surface mount substrate 602 through a plurality of pillar interconnects 632 and the plurality of solder interconnects 630. The integrated passive device 605 may be coupled to the surface mount substrate 602 through a plurality of solder interconnects 650. The integrated passive device 605 may be coupled to the surface mount substrate 602 through a plurality of pillar interconnects 652 and the plurality of solder interconnects 650.

The package (e.g., 600) may be implemented in a radio frequency (RF) package. The RF package may be a radio frequency front end (RFFE) package. A package (e.g., 600) may be configured to provide Wireless Fidelity (Wi-Fi) communication and/or cellular communication (e.g., 2G, 3G, 4G, 5G). The package (e.g., 600) may be configured to support Global System for Mobile (GSM) Communications, Universal Mobile Telecommunications System (UMTS), and/or Long-Term Evolution (LTE). The package (e.g., 600) may be configured to transmit and receive signals having different frequencies and/or communication protocols.

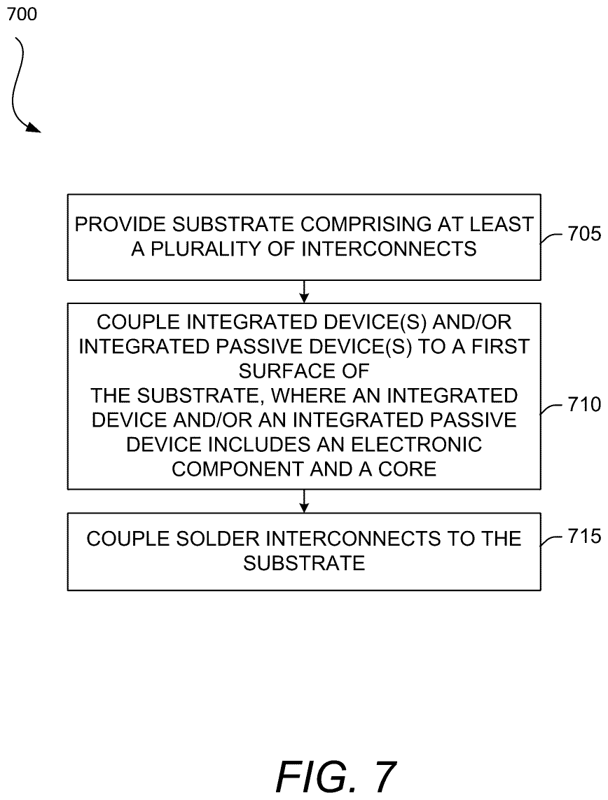

FIG. 7 illustrates an example method 700 for providing or fabricating a package that includes an integrated device comprising a power management control circuit, according to aspects of the disclosure. In some implementations, the method 700 of FIG. 7 may be used to provide or fabricate the package 600 of FIG. 6 described in the disclosure. However, the method 700 may be used to provide or fabricate any of the packages described in the disclosure.

It should be noted that the method of FIG. 7 may combine one or more processes in order to simplify and/or clarify the method for providing or fabricating a package that includes an integrated device comprising a power management control circuit, according to aspects of the disclosure. In some implementations, the order of the processes may be changed or modified.

The method provides (at 705) a substrate (e.g., 602). The substrate 602 may be provided by a supplier or fabricated. The substrate 602 includes at least one dielectric layer 620, and a plurality of interconnects 622. The substrate 602 may include an embedded trace substrate (ETS). In some implementations, the at least one dielectric layer 620 may include prepreg layers.

The method couples (at 710) at least one integrated device (e.g., 603) to the first surface of the substrate (e.g., 602). For example, the integrated device 603 may be coupled to the substrate 602 through the plurality of pillar interconnects 632 and the plurality of solder interconnects 630. The plurality of pillar interconnects 632 may be optional. The plurality of solder interconnects 630 are coupled to the plurality of interconnects 622. A solder reflow process may be used to couple the integrated device 603 to the plurality of interconnects through the plurality of solder interconnects 630.

The method also couples (at 710) at least one integrated passive device (e.g., 605) to the first surface of the substrate (e.g., 602). For example, the integrated passive device 605 may be coupled to the substrate 602 through the plurality of pillar interconnects 652 and the plurality of solder interconnects 650. The plurality of pillar interconnects 652 may be optional. The plurality of solder interconnects 650 are coupled to the plurality of interconnects 622. A solder reflow process may be used to couple the integrated passive device 605 to the plurality of interconnects through the plurality of solder interconnects 650.

The method couples (at 715) a plurality of solder interconnects (e.g., 610) to the second surface of the substrate (e.g., 602). A solder reflow process may be used to couple the plurality of solder interconnects 610 to the substrate.

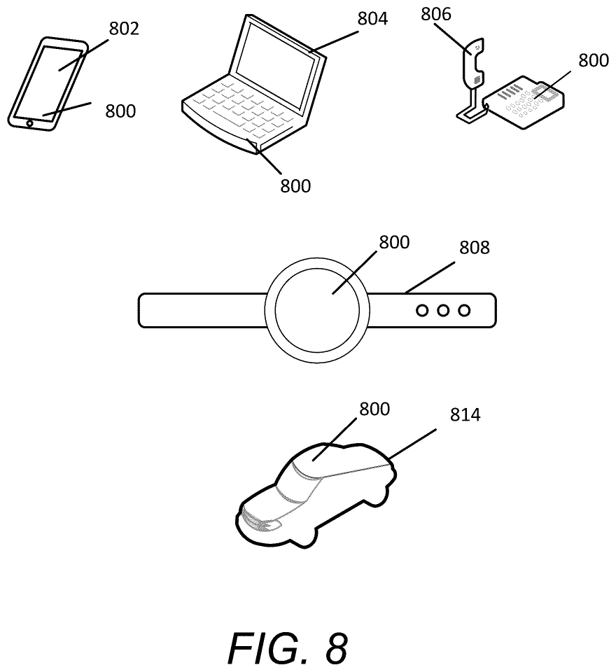

FIG. 8 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 802, a laptop computer device 804, a fixed location terminal device 806, a wearable device 808, or automotive vehicle 813 may include a device 800 as described herein. The device 800 may be, for example, any of the devices and/or integrated circuit (IC) packages described herein. The devices 802, 804, 806 and 808 and the vehicle 813 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:
Aspect 1. An electronic device, comprising: a die substrate; a substrate overlying the die substrate, the substrate having one or more non-magnetic dielectric layers, and a central region and a side region adjacent the central region; a set of metallizations extending through the one or more non-magnetic dielectric layers of the central region of the substrate, wherein the set of metallizations are connected to control lines of the die substrate; and a solenoid thin-film inductor (TFI) disposed in the one or more non-magnetic dielectric layers of the side region, the solenoid TFI comprising a central magnetic block, one or more magnetic blocks disposed adjacent to opposite ends of the central magnetic block, and conductive windings disposed about the central magnetic block.
Aspect 2. The electronic device of aspect 1, wherein: the one or more magnetic blocks comprise a first magnetic block disposed at a first end of the central magnetic block and a second magnetic block disposed at a second end of the central magnetic block.
Aspect 3. The electronic device of aspect 2, wherein: the first magnetic block, the second magnetic block, and the central magnetic block are formed as a single sheet of magnetic material.
Aspect 4. The electronic device of any of aspects 2 to 3, wherein: the first magnetic block and the second magnetic block each have a width greater than a width of the central magnetic block and a length at least 20 percent of a length of the central magnetic block.
Aspect 5. The electronic device of any of aspects 1 to 4, wherein: the conductive windings of the solenoid TFI are connected to power lines of the die substrate.
Aspect 6. The electronic device of any of aspects 1 to 5, wherein: the conductive windings include a first patterned metallization layer disposed above the central magnetic block; a second patterned metallization layer disposed below the central magnetic block; and a plurality of pillars electrically connecting the first patterned metallization layer and the second patterned metallization layer.
Aspect 7. The electronic device of any of aspects 1 to 6, further comprising: a set of one or more thermal blocks exterior to the solenoid TFI and at least partially embedded in the one or more non-magnetic dielectric layers.
Aspect 8. The electronic device of aspect 7, wherein: the set of one or more thermal blocks are formed from an electrically conductive material.
Aspect 9. The electronic device of any of aspect 7, wherein: the one or more thermal blocks are formed from an electrical insulator material.
Aspect 10. The electronic device of any of aspects 1 to 9, wherein: the substrate includes a further side region adjacent the central region and opposite the side region; and a further solenoid TFI disposed in the one or more non-magnetic dielectric layers of the further side region of the substrate, wherein the further solenoid TFI comprises a central magnetic block, one or more magnetic blocks disposed adjacent to opposite ends of the central magnetic block, and conductive windings formed about the central magnetic block.
Aspect 11. The electronic device of any of aspects 1 to 10, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.
Aspect 12. A power management circuit, comprising: a die substrate; a substrate overlying the die substrate, the substrate having one or more non-magnetic dielectric layers, a central region, and a side region adjacent the central region; a set of metallizations extending through the one or more non-magnetic dielectric layers of the central region of the substrate, wherein the set of metallizations are connected to control lines of the die substrate; and a solenoid thin-film inductor (TFI) disposed in the one or more non-magnetic dielectric layers of the side region, the solenoid TFI comprising a central magnetic block, one or more magnetic blocks disposed adjacent to opposite ends of the central magnetic block, and conductive windings disposed about the central magnetic block.
Aspect 13. The power management circuit of aspect 12, wherein: the one or more magnetic blocks comprise a first magnetic block disposed at a first end of the central magnetic block and a second magnetic block disposed at a second end of the central magnetic block.
Aspect 14. The power management circuit of aspect 13, wherein: the first magnetic block, the second magnetic block, and the central magnetic block are formed as a single sheet of magnetic material.
Aspect 15. The power management circuit of any of aspects 13 to 14, wherein: the first magnetic block and the second magnetic block each have a width greater than a width of the central magnetic block and a length at least 20 percent of a length of the central magnetic block.
Aspect 16. The power management circuit of any of aspects 12 to 15, wherein: the die substrate is a power management integrated circuit (PMIC) substrate; and the conductive windings of the solenoid TFI are connected to power lines of the PMIC substrate.
Aspect 17. The power management circuit of any of aspects 12 to 16, wherein: the conductive windings include a first patterned metallization layer disposed above the central magnetic block; a second patterned metallization layer disposed below the central magnetic block; and a plurality of pillars electrically connecting the first patterned metallization layer and the second patterned metallization layer.
Aspect 18. The power management circuit of any of aspects 12 to 17, further comprising: a set of one or more thermal blocks exterior to the solenoid TFI and at least partially embedded in the one or more non-magnetic dielectric layers.
Aspect 19. The power management circuit of any of aspects 12 to 18, wherein: the substrate includes a further side region adjacent the central region and opposite the side region; and a further solenoid TFI disposed in the one or more non-magnetic dielectric layers of the further side region of the substrate, wherein the further solenoid TFI comprises a central magnetic block, one or more magnetic blocks disposed adjacent to opposite ends of the central magnetic block, and conductive windings formed about the central magnetic block.
Aspect 20. A method of fabricating a power management circuit, comprising: receiving a die substrate for processing; and forming a substrate over the die substrate, the substrate having one or more non-magnetic dielectric layers, a central region and a side region adjacent the central region, a set of metallizations extending through the one or more non-magnetic dielectric layers of the central region of the substrate, wherein the set of metallizations are connected to control lines of the die substrate, a solenoid thin-film inductor (TFI) disposed in the one or more non-magnetic dielectric layers of the side region, the solenoid TFI comprising a central magnetic block, one or more magnetic blocks disposed adjacent to opposite ends of the central magnetic block, and conductive windings disposed about the central magnetic block.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
a die substrate;
a substrate overlying the die substrate, the substrate having
one or more non-magnetic dielectric layers, and
a central region and a side region adjacent the central region;
a set of metallizations extending through the one or more non-magnetic dielectric layers of the central region of the substrate, wherein the set of metallizations are connected to control lines of the die substrate, and
a solenoid thin-film inductor (TFI) disposed in the one or more non-magnetic dielectric layers of the side region, the solenoid TFI comprising
a central magnetic block,
one or more magnetic blocks disposed adjacent to opposite ends of the central magnetic block, and
conductive windings disposed about the central magnetic block.

2. The electronic device of claim 1, wherein:
the one or more magnetic blocks comprise a first magnetic block disposed at a first end of the central magnetic block and a second magnetic block disposed at a second end of the central magnetic block.

3. The electronic device of claim 2, wherein:
the first magnetic block, the second magnetic block, and the central magnetic block are formed as a single sheet of magnetic material.

4. The electronic device of claim 2, wherein:
the first magnetic block and the second magnetic block each have a width greater than a width of the central magnetic block and a length at least 20 percent of a length of the central magnetic block.

5. The electronic device of claim 1, wherein:
the conductive windings of the solenoid TFI are connected to power lines of the die substrate.

6. The electronic device of claim 1, wherein:
the conductive windings include
a first patterned metallization layer disposed above the central magnetic block;
a second patterned metallization layer disposed below the central magnetic block; and
a plurality of pillars electrically connecting the first patterned metallization layer and the second patterned metallization layer.

7. The electronic device of claim 1, further comprising:
a set of one or more thermal blocks exterior to the solenoid TFI and at least partially embedded in the one or more non-magnetic dielectric layers.

8. The electronic device of claim 7, wherein:
the set of one or more thermal blocks are formed from an electrically conductive material.

9. The electronic device of claim 7, wherein:
the one or more thermal blocks are formed from an electrical insulator material.

10. The electronic device of claim 1, wherein:
the substrate includes a further side region adjacent the central region and opposite the side region; and
a further solenoid TFI disposed in the one or more non-magnetic dielectric layers of the further side region of the substrate, wherein the further solenoid TFI comprises
a central magnetic block,
one or more magnetic blocks disposed adjacent to opposite ends of the central magnetic block, and
conductive windings formed about the central magnetic block.

11. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

12. A power management circuit, comprising:
a die substrate;
a substrate overlying the die substrate, the substrate having
one or more non-magnetic dielectric layers,
a central region, and
a side region adjacent the central region;
a set of metallizations extending through the one or more non-magnetic dielectric layers of the central region of the substrate, wherein the set of metallizations are connected to control lines of the die substrate; and
a solenoid thin-film inductor (TFI) disposed in the one or more non-magnetic dielectric layers of the side region, the solenoid TFI comprising
a central magnetic block,
one or more magnetic blocks disposed adjacent to opposite ends of the central magnetic block, and
conductive windings disposed about the central magnetic block.

13. The power management circuit of claim 12, wherein:
the one or more magnetic blocks comprise a first magnetic block disposed at a first end of the central magnetic block and a second magnetic block disposed at a second end of the central magnetic block.

14. The power management circuit of claim 13, wherein:
the first magnetic block, the second magnetic block, and the central magnetic block are formed as a single sheet of magnetic material.

15. The power management circuit of claim 13, wherein:
the first magnetic block and the second magnetic block each have a width greater than a width of the central magnetic block and a length at least 20 percent of a length of the central magnetic block.

16. The power management circuit of claim 12, wherein:
the die substrate is a power management integrated circuit (PMIC) substrate; and
the conductive windings of the solenoid TFI are connected to power lines of the PMIC substrate.

17. The power management circuit of claim 12, wherein:
the conductive windings include
a first patterned metallization layer disposed above the central magnetic block;
a second patterned metallization layer disposed below the central magnetic block; and
a plurality of pillars electrically connecting the first patterned metallization layer and the second patterned metallization layer.

18. The power management circuit of claim 12, further comprising:
a set of one or more thermal blocks exterior to the solenoid TFI and at least partially embedded in the one or more non-magnetic dielectric layers.

19. The power management circuit of claim 12, wherein:
the substrate includes a further side region adjacent the central region and opposite the side region; and
a further solenoid TFI disposed in the one or more non-magnetic dielectric layers of the further side region of the substrate, wherein the further solenoid TFI comprises
a central magnetic block,
one or more magnetic blocks disposed adjacent to opposite ends of the central magnetic block, and
conductive windings formed about the central magnetic block.

20. A method of fabricating a power management circuit, comprising:
receiving a die substrate for processing; and
forming a substrate over the die substrate, the substrate having
one or more non-magnetic dielectric layers,
a central region and a side region adjacent the central region,
a set of metallizations extending through the one or more non-magnetic dielectric layers of the central region of the substrate, wherein the set of metallizations are connected to control lines of the die substrate,
a solenoid thin-film inductor (TFI) disposed in the one or more non-magnetic dielectric layers of the side region, the solenoid TFI comprising
a central magnetic block,
one or more magnetic blocks disposed adjacent to opposite ends of the central magnetic block, and
conductive windings disposed about the central magnetic block.
